(19) United States
(12) Patent Application Publication
(10) Pub. No.: US 2004/0222859 A1
(43) Pub. Date: Nov. 11, 2004

(54) Distributed oscillator architectures

(76) Inventors: Seyed-Ali Hajimiri, Pasadena, CA (US); Hui Wu, Pasadena, CA (US)

Correspondence Address: CHRISTOPHER J. ROURK, AKIN, GUMP, STRAUSS, HAUER & FELD, L.L.P., P O BOX 688, DALLAS, TX, 75313-0688, US

(21) Appl. No.: 10/434,297

(22) Filed: May 8, 2003

(51) Int. Cl. H03B 11/10

(52) U.S. Cl. 331/107 DP

(57) ABSTRACT

A voltage controlled oscillator is provided. The voltage controlled oscillator includes a traveling-wave amplifier having two inputs and two outputs, such as would be formed by a first transmission line having a first input and a first output and a second transmission line having a second input and a second output. The first output of the traveling-wave amplifier is connected to the first input. A delay is connected between the second output and the second input, so as to provide a voltage controlled oscillator that requires minimal power to operate.

### FEDERAL SUPPORT STATEMENT

The U.S. Government has a paid-up license in this invention and the right in limited circumstances to require the patent owner to license others on reasonable terms as provided for by the terms of ECS-0083220 awarded by NSF.

### FIELD OF THE INVENTION

The present invention relates generally to the field of oscillators and more particularly to distributed oscillators (tunable or not tunable), including distributed voltage-controlled oscillators (DVCO's), which are tunable distributed oscillators tuned by a control signal.

### BACKGROUND OF THE INVENTION

Oscillators are essential building blocks in modern communication systems and other applications. A distributed oscillator can operate at frequencies close to or beyond the cut-off frequency of transistors, which allows them to be used in extremely high frequency applications, such as proposed broadband wireless communications at 60 GHz or fiber-optic communication systems at 40 Gb/s and beyond. Furthermore, existing lumped solutions for integrated, high frequency oscillators are inadequate in many regards. For example, while it is possible to design an LC oscillator on a silicon substrate at up to 10 GHz, it is difficult to achieve a wide tuning range and good phase noise performance. The problem is further exacerbated as the operation frequency increases—as the operation frequency approaches the cut-off frequency of the transistors, it is even difficult to achieve the oscillation at all. In addition, distributed oscillators provide a low-cost system-on-a-chip solution for mobile phone handsets, wireless LAN products, and other applications where low-speed mainstream CMOS processes are preferred and thus LC oscillators or other prior art oscillators become unsuitable.

The initial idea of distributed oscillators was proposed by Skvor, et al. in 1992 to build an oscillator by operating a traveling-wave amplifier (also known as distributed amplifier) in the reverse gain mode. See, “Novel Decade Electronically Tunable Microwave Oscillator based on the Distributed Amplifier,” Electronics Letters, vol. 28, no. 17, pp. 1647 1648, August 1992. Later, a 4 GHz, distributed oscillator was demonstrated using discrete pHEMTs and microstrip lines on a printed circuit board. See, “The Distributed Oscillator at 4 GHz,” IEEE Trans. MTT, vol. 46, no. 12, pp. 2240 2243, December 1998. In 1999 another group showed an integrated distributed oscillator with off-chip termination using 0.18 μm CMOS technology. See Kieveland B., et al., “Monolithic CMOS Distributed Amplifier and Oscillator,” IEEE Int. Solid State Circ. Conf., Paper MP 4.3, February 1999. Most recently, the inventors' work led to new tuning techniques for distributed oscillators. See U.S. Pat. No. 6,396,359 B1.

Despite the earlier advances, the full potential of distributed oscillators has yet to be exploited. Due to its distributed nature, a distributed oscillator has better phase noise performance than its lumped counterpart, which is the most important characteristic of an oscillator. However, the conventional distributed oscillator architecture compromises its phase noise performance because of that (a) its dummy loads waste substantial amount of energy, which does not contribute to enhance the oscillation amplitude; (b) there is inherent imbalance between the two transmission lines in a conventional distributed oscillator architecture, which causes extra energy loss since signals on two transmission lines cannot maintain synchronization. Even if the two transmission lines are meticulously designed to be balanced, device nonlinearity in large-signal operation, inaccurate device or transmission line modeling, process and temperature variation all make the design far from robust, repeatable or reliable. Secondly, there is a technical challenge need to be addressed in the physical design of distributed oscillators, namely, the ground path for ac signals. This is a general problem in RF circuit design, but it is particularly difficult in the case of a distributed oscillator because of the relatively long distance between ground points of amplification devices in a distributed oscillator. Thirdly, a good output buffer is needed, which should conserve the distributed nature of a distributed oscillator. Injection locking can be utilized in a distributed oscillator to achieve multiple-phase outputs.

### SUMMARY OF THE INVENTION

The present invention, which addresses these needs, sufficiently resides in a distributed oscillator which operates at extremely high frequencies, and can be integrated on an integrated circuit chip.

In particular, a distributed oscillator includes a core structure, namely, a traveling-wave amplification section (TWAS). A TWAS has four ports, such as would be formed by a first transmission line between the first two ports, a second transmission line between the last two ports, and amplification devices between the two transmission lines. An input signal enters the first port of a TWAS and travels down to its second port. The input signal is also amplified and the amplified signal is generated at one of the other two ports of the TWAS. In a conventional distributed oscillator, the amplified output port of a TWAS is connected properly to its first input port and thus forms a feedback loop, while the other two ports are terminated with matched terminations. More advanced architectures to construct a distributed oscillator are discloses in the present invention, which incorporate more TWAS', more feedback paths, and additional circuitry to achieve better performance.

The features and advantages of the present invention should become more apparent from the following description of the preferred embodiments, taken in conjunction with the accompanying drawings, which illustrate, by way of example, the principles of the invention.

### BRIEF DESCRIPTION OF THE SEVERAL VIEWS OF THE DRAWINGS

FIG. 1 is a diagram of a conventional distributed oscillator, which includes a traveling-wave amplification section (TWAS);

FIG. 2 is a diagram of a distributed oscillator having a double-feedback architecture in accordance with an exemplary embodiment of the present invention;

FIG. 3 is a diagram of a distributed oscillator having a balanced architecture in accordance with an exemplary embodiment of the present invention;

FIG. 4 is a diagram of a distributed oscillator that utilizes a balanced configuration with double feedback in accordance with an exemplary embodiment of the present invention.

FIGS. 5A and 5B are diagrams of a distributed oscillator with a TWAS buffer in accordance with an exemplary embodiment of the present invention; and

FIGS. 6A and 6B are diagrams of an injection-locked distributed oscillator in accordance with an exemplary embodiment of the present invention.

### DETAILED DESCRIPTION OF THE PREFERRED EMBODIMENTS

The invention summarized above and defined by the enumerated claims may be better understood by referring to the following detailed description, which should be read in conjunction with the accompanying drawings. This detailed description of particular preferred and exemplary embodiments, set out below to enable one to build and use particular implementations of the invention, is not intended to limit the enumerated claims, but to serve only as particular examples thereof. The particular examples set out below are the preferred specific implementations of integrated distributed oscillators. Prior to describing the invention, some background on the operation of integrated distributed oscillators will be illustrative.

### II. Conventional Distributed Oscillators

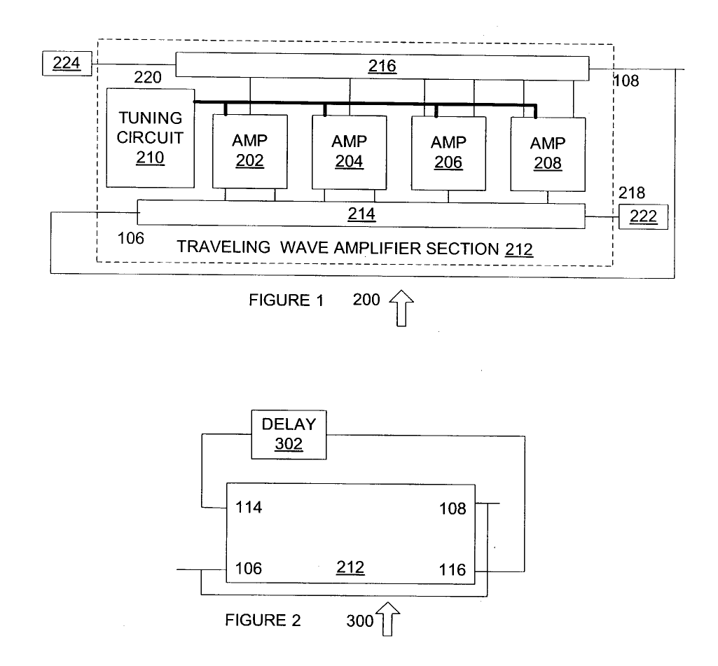

FIG. 1 is a diagram of a conventional distributed oscillator 200, which includes traveling-wave amplifier section (TWAS) 212. TWAS 212 is adapted to be used in conjunction with FIGS. 2 through 6A, as described further herein. TWAS 212 in the exemplary embodiment shown includes input transmission line 214 and output transmission line 216, with generic amplification devices 202 through 208. Input transmission line 214 and output transmission line 216 can be implemented as microstrip lines, coplanar striplines, coplanar waveguides, or other suitable transmission lines. Amplification devices 202 through 208 can be transistors, amplifiers, or other suitable circuits.

TWAS 212 has input 106, output 108, and dummy outputs 218 and 220. The forward (to the right in the figure) wave on input transmission line 214 is amplified by each amplification device. The incident wave on output transmission line 216 travels forward in synchronization with the traveling wave on input transmission line 214. Each amplification device adds power in phase to the signal at each tap point on output transmission line 216.

The forward traveling wave on input transmission line 214 is absorbed at dummy output 218 by dummy termination load 222, which is matched to the loaded characteristic impedance of input transmission line 214. The backward (traveling to the left) wave on the output transmission line 216 is absorbed at dummy output 220 by dummy termination load 224, which is matched to loaded characteristic impedance of output transmission line 216. The energy or RF power is wasted on dummy loads 222 and 224, which lowers the circuit power efficiency and potentially degrades the phase noise performance. Dummy loads 222 and 224 also result in difficulty in implementations—since on-chip passive components (resistors, capacitors, and inductors) have limited range and poor tolerance in absolute values, the required circuitry for loads matched to some predetermined impedance value (e.g., 50 ohm) can be either difficult to implement on-chip, or very inaccurate. The latter case leads to excessive reflections from dummy loads 222 and 224 back into TWAS 212, and thus degrades its performance.

Distributed oscillator 200 includes a feedback path from output 108 to input 106. The feedback path can use ac coupling, dc coupling, or other suitable circuitry. A feedback loop can be formed for each amplification device 202-208. Ideally, signals travel in all these feedback loops in synchronization, and thus they can be considered as a single feedback loop. Steady oscillation will be established if the gain in the feedback loop is equal to 1 and the phase shift in the feedback loop is equal to multiple 360 degrees, given that necessary startup conditions are satisfied. Accordingly, the oscillation frequency is determined by the total time delay in the feedback loop.

In this exemplary embodiment, the phase velocity is equal on the two loaded transmission lines, i.e., input transmission line 214 and output transmission line 216 loaded with the input or output admittance (including capacitance and conductance) of amplification devices, respectively. In other exemplary embodiments, there can be an imbalance between the two loaded transmission lines, which comes from the fact that the value of input admittance of amplification devices is usually quite different from that of output admittance. For example, the input capacitance of a NMOS transistor in a common-source configuration, Cgs, is usually much larger than the output capacitance, Cgd+Cdb. The input and output admittance of amplification devices can also be nonlinear with regard to voltage, while an oscillator always operates in large signal, i.e., with large voltage swing or oscillation amplitude. Since it can be difficult to predict the oscillation amplitude, especially at RF frequencies due to inadequate and inaccurate models, it can be difficult to achieve good balance between the two loaded lines only by design.

### II. Double-Feedback Distributed Oscillators

FIG. 2 is a diagram of a double-feedback distributed oscillator 300 in accordance with an exemplary embodiment of the present invention. Double-feedback distributed oscillator 300 uses a double-feedback architecture to avoid the need for dummy matched loads, and can operate at a higher power efficiency, resulting in improved phase noise performance. Double-feedback distributed oscillator 300 can also be used where on-chip matched loads are unavailable or their values have poor tolerance.

In addition to the feedback path from output 108 of TWAS 212 to input 106, a second feedback path from 116 to 114 is provided through delay 302. In one exemplary embodiment, the forward traveling-wave on input transmission line 214 is not absorbed by a dummy matched load 222; instead, it is provided to output transmission line 216, and thus contributes to the total synchronized signal at output 108.

In one exemplary embodiment, delay 302 can be used to account for extra delay introduced by amplification devices 202 through 208. Without delay 302, the signal fed back from 116 to 114 could be ahead of signals amplified by each amplification device in phase. In this manner, the synchronization of signals on output transmission line 42 is conserved. Further, delay 302 makes the circuit asymmetric for signals traveling in two directions: the signals on both transmission lines are synchronized in the forward direction (i.e., towards the right in FIG. 1), but not so in the backward direction (i.e., towards the left in FIG. 1). In this manner, the oscillation only happens in the forward direction at the steady state of the oscillator, and there exist pre-determined phase relations along both transmission lines. Delay 302 can be implemented using an additional section of transmission lines or other suitable systems or components.

### II. Balanced Distributed Oscillator

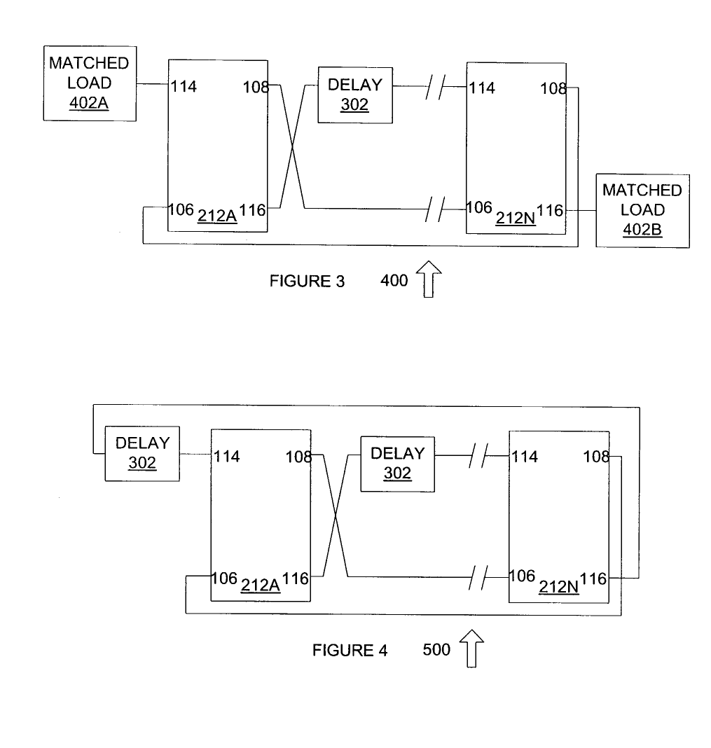

FIG. 3 is a diagram of a balanced distributed oscillator 400 in accordance with an exemplary embodiment of the present invention. Balanced distributed oscillator 400 uses multiple TWAS to form a balanced structure such as to provide improved phase-velocity balance between the two transmission lines, and thus systematically overcome the inherent imbalance due to device characteristics, large-signal operation, nonlinearity, and process or temperature variations.

Balanced distributed oscillator section 400 includes multiple TWAS 212A to 212N, where “N” is a suitable integer. A suitable number of sections can be used, although when a single section is used, it is a conventional distributed oscillator. In one exemplary embodiment, an even number of sections can prevent imbalance caused by uniform characteristics of input transmission line 214 and output transmission line 216, such as where the impedance of input transmission line 214 is uniformly different from the impedance of output transmission line 216. Output 108 from TWAS 212A is connected to input 106 of the next TWAS, such as 212N where only 2 sections are used. Output 116 of TWAS 212A is connected to input 114 of the next TWAS, such as 212N, through delay 302. Matched loads 402A and 402B are coupled to TWAS 212A input 114 and TWAS 212N output 116, respectively.

In this exemplary embodiment, the distinctive input and output transmission lines of the conventional distributed oscillator architecture are replaced by two or more transmission lines that cross each other between adjacent TWAS and exchange their roles as input or output transmission lines. For an even number of TWAS, these two lines should have almost identical device loading and thus similar phase velocity to the first order. In this manner, signal synchronization on these two lines can be well maintained, even if there is inherent imbalance within each TWAS. Therefore, oscillation frequency accuracy and stability can be greatly improved, which corresponds to better phase noise performance and less stringent design requirements. Balanced distributed oscillator 400 can also reduce unwanted effects caused by process or temperature variations.

### III. Double-Balanced Distributed Oscillator

FIG. 4 is a diagram of a double-balanced distributed oscillator 500 in accordance with an exemplary embodiment of the present invention, which combines a balanced distributed oscillator configuration with double feedback paths. In addition to all the benefits of both double-feedback and balanced distributed oscillators, double-balanced distributed oscillator 500 also has improved symmetry between the transmission lines, which makes the design more robust to inaccurate modeling and improves the ease of layout.

### IV. TWAS-Buffered Distributed Oscillators

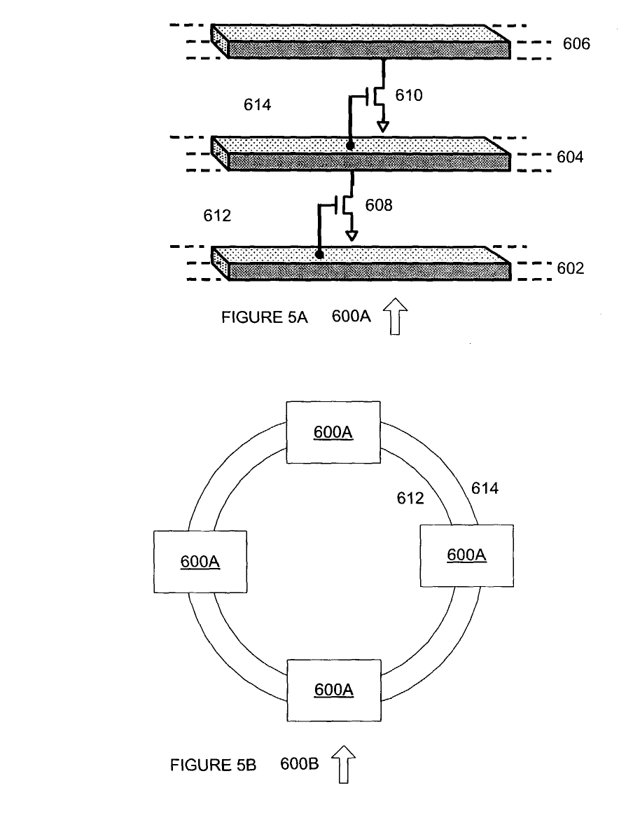

FIGS. 5A and 5B show TWAS-buffered distributed oscillator 600B and detail section 600A and in accordance with an exemplary embodiment of the present invention. TWAS-buffered distributed oscillator section 600A includes input transmission line 602, output transmission line 604, and amplification device 608. In addition, TWAS buffer 614 is formed by third transmission line 606, amplification device 610 and also output transmission line 604, which is shared by distributed oscillator 612 and TWAS 614. TWAS 614 amplifies the signal from output transmission line 604.

In one exemplary embodiment, a TWAS can be used as a buffer, in which there is a single point-to-point connection between the output of the distributed oscillator and the input of the traveling-wave amplifier. In the exemplary embodiment shown in FIGS. 5A and 5B, TWA-buffered distributed oscillator 600 has multiple taps as the interface between the core of distributed oscillator 612 and TWAS 614.

Further, TWA-buffered distributed oscillator 600B can provide multiple-phase outputs by using a number of short TWA buffering sections with a pre-defined interval. In one exemplary embodiment, four short TWA buffering sections can be spaced to provide quadrature outputs, which is required in most modem digital communication systems.

FIG. 5B shows an exemplary embodiment of distributed oscillator 600B with four tap points between distributed oscillator 612 and TWAS 614. Other configurations can also or alternatively be used, such as square configurations with straight transmission line segments, polyhedron-shapes to provide phase relations other than quadrature (such as triangles, pentagons, hexagons, or other suitable shapes), or other suitable configurations.

### V. Injection Locked Distributed Oscillators

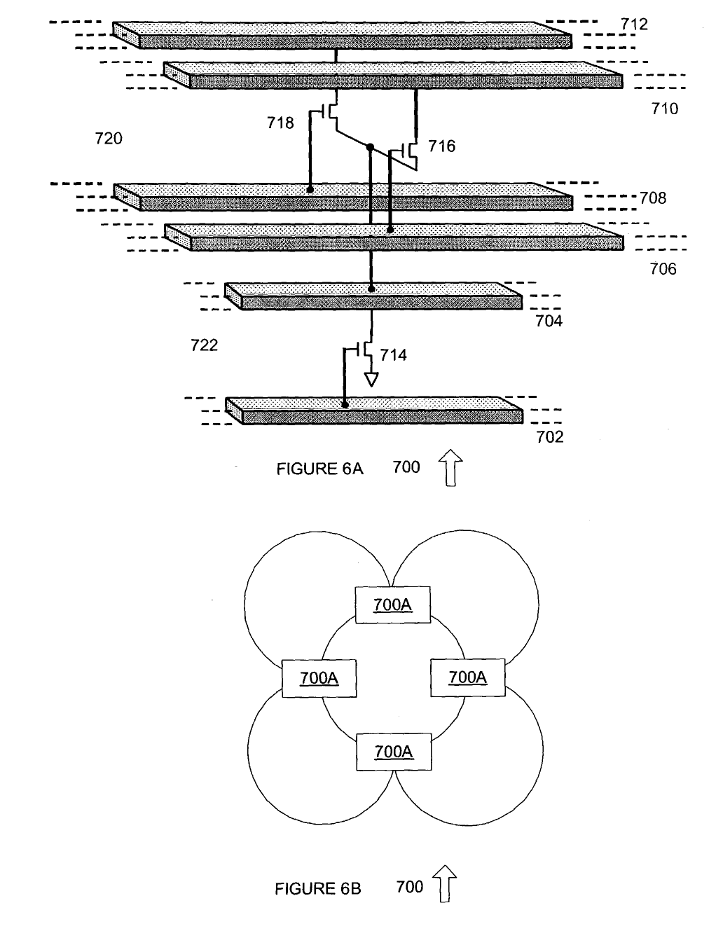

FIGS. 6A and 6B are diagrams of an injection locked distributed oscillator 700B and exemplary node 700A with injection locking in accordance with an exemplary embodiment of the present invention. Injection locked distributed oscillator 700B includes a first distributed oscillator section 722 and a second distributed oscillator section 720. In the exemplary embodiment shown, distributed oscillator section 720 has a differential architecture, which consists of differential input transmission lines 706 and 708, differential output transmission lines 710 and 712, and differential pair of amplification devices 716 and 718. Distributed oscillator 722 has a single-ended architecture, which consists of input transmission line 702, output transmission line 704, and amplification device 714. Distributed oscillator section 720 and 722 are injection locked to each other through the tail node of differential pair 716 and 718 (the common node where amplification device 716 and 718 joins).

In this manner, injection locking can be used to improve phase noise response. The exemplary injection node 700A can be provided at a suitable number of points, such as at four points, with first distributed oscillator section 722 and second distributed oscillator section 720 coupled in a closed circuit or other suitable configurations, such as those shown in FIG. 6B.

Having thus described exemplary embodiments of the invention, it will be apparent that further alterations, modifications, and improvements will also occur to those skilled in the art. Further, it will be apparent that the present system is not limited to use with CMOS or bipolar technology. The techniques described herein are equally applicable to the distributed oscillators using other active devices such as vacuum tubes, for example. Such alterations, modifications, and improvements, though not expressly described or mentioned above, are nonetheless intended and implied to be within the spirit and scope of the invention. Accordingly, the foregoing discussion is intended to be illustrative only; the invention is limited and defined only by the various following claims and equivalents thereto.

1. A voltage controlled oscillator comprising:
a traveling wave amplifier section having two inputs and two outputs, wherein the first output is coupled to the first input; and
a delay coupled between the second output and the second input.

2. The voltage controlled oscillator of claim 1 wherein the traveling wave amplifier section further comprises a single transmission line pair.

3. The voltage controlled oscillator of claim 1 wherein the traveling wave amplifier section further comprises a plurality of transmission line pairs.

4. The voltage controlled oscillator of claim 1 further comprising a second traveling wave amplifier section having two inputs and two outputs, wherein a matched load is coupled to the first input of the first traveling-wave amplifier section, the first input of the second traveling-wave amplifier section is coupled to the delay, the first output of the first traveling-wave amplifier section is coupled to the second input of the second traveling-wave amplifier section, the first output of the second traveling-wave amplifier section is coupled to the second input of the first traveling-wave amplifier section, and a second matched load is coupled to the second output of the second traveling-wave amplifier section.

5. The voltage controlled oscillator of claim 1 further comprising a second traveling-wave amplifier section having two inputs and two outputs, wherein the first input of the second traveling-wave amplifier section is coupled to the delay, the first output of the first traveling-wave amplifier section is coupled to the second input of the second traveling-wave amplifier section, the first output of the second traveling-wave amplifier section is coupled to the second input of the first traveling-wave amplifier section, and a second delay is coupled to the second output of the second traveling-wave amplifier section and the first input of the first traveling-wave amplifier section.

6. The voltage controlled oscillator of claim 1 further comprising a plurality of additional traveling-wave amplifier sections having two inputs and two outputs with a plurality of delays coupled to the second output of each of the plurality of additional traveling-wave amplifier sections except the last, wherein a matched load is coupled to the first input of the first traveling-wave amplifier section, the first input of each of the plurality of additional traveling-wave amplifier sections is coupled to the delay of the previous traveling-wave amplifier, the first output of each of the plurality of additional traveling-wave amplifier sections except the last are coupled to the second input of the next additional traveling-wave amplifier section, the first output of the last additional traveling-wave amplifier section is coupled to the second input of the first traveling-wave amplifier section, and a second matched load is coupled to the second output of the last additional traveling-wave amplifier section.

7. The voltage controlled oscillator of claim 1 further comprising a plurality of additional traveling-wave amplifier sections having two inputs and two outputs with a plurality of delays coupled to the second output of each of the plurality of additional traveling-wave amplifier sections, wherein the first input of the first traveling-wave amplifier section is coupled to the last delay of the last additional traveling-wave amplifier section, the first input of each of the plurality of additional traveling-wave amplifier sections is coupled to the delay of the previous traveling-wave amplifier section, the first output of each of the plurality of additional traveling-wave amplifier sections except the last are coupled to the second input of the next additional traveling-wave amplifier section, and the first output of the last additional traveling-wave amplifier section is coupled to the second input of the first traveling-wave amplifier section.

8. The voltage controlled oscillator of claim 1 wherein the traveling-wave amplifier section has a tunable frequency of oscillation.

9. A traveling-wave amplifier section comprising:
a first transmission line with an input and an output;
a second transmission line with an input and an output coupled to the input of the first transmission line;
two or more three terminal active devices each having a biasing input terminal coupled to the first transmission line and an output terminal coupled to the second transmission line; and
a delay coupled to the input of the first transmission line and the output of the second transmission line.

10. The traveling-wave amplifier section of claim 9 further comprising:
a plurality of additional first transmission lines each with an input and an output;
a plurality of additional second transmission lines each with an output and an input coupled to the output of the previous first transmission line;
two or more additional three terminal active devices for each additional first and second transmission lines, each of the two or more additional three terminal active devices having a biasing input terminal coupled to the corresponding additional first transmission line and an output terminal coupled to the corresponding second additional transmission line; and
a plurality of additional delays, each additional delay except the last coupled to the input of one of the additional first transmission lines and the output of the previous second transmission line, the last delay coupled to the input of the first transmission line and the output of the last additional second transmission line.

11. The traveling-wave amplifier section of claim 9 further comprising:
a plurality of additional first transmission lines each with an input and an output;
a plurality of additional second transmission lines each with an output and an input coupled to the output of the previous first transmission line;
two or more additional three terminal active devices for each additional first and second transmission lines, each of the two or more additional three terminal active devices having a biasing input terminal coupled to the corresponding additional first transmission line and an output terminal coupled to the corresponding second additional transmission line;
a plurality of additional delays, each delay coupled to the input of one of the additional first transmission lines and the output of the previous second transmission line;
a first matched load coupled to the input of the first transmission line; and
a second matched load coupled to the output of the last second additional transmission line.

12-18. (Cancelled).

19. A voltage controlled oscillator comprising:
a first traveling wave amplifier section having a single transmission line pair with two inputs and two outputs, wherein the first output is coupled to the first input;
a delay coupled between the second output and the second input of the first traveling wave amplifier section;
a second traveling wave amplifier section having a single transmission line with two inputs and two outputs; and
wherein a matched load is coupled to the first input of the first traveling-wave amplifier section, the first input of the second traveling-wave amplifier section is coupled to the delay, the first output of the first traveling-wave amplifier section is coupled to the second input of the second traveling-wave amplifier section, the first output of the second traveling-wave amplifier section is coupled to the second input of the first traveling-wave amplifier section, and a second matched load is coupled to the second output of the second traveling-wave amplifier section.

20. The voltage controlled oscillator of claim 19 wherein the first traveling wave amplifier section further comprises a plurality of transmission line pairs.

21. The voltage controlled oscillator of claim 19 wherein the second traveling wave amplifier section further comprises a plurality of transmission line pairs.

22. The voltage controlled oscillator of claim 19 further comprising a plurality of additional traveling-wave amplifier sections coupled to the first traveling wave amplifier section and the second traveling wave amplifier section, each of the plurality of additional traveling wave amplifier sections having two inputs and two outputs with a plurality of delays coupled to the second output of each of the plurality of additional traveling-wave amplifier sections except the last, wherein a matched load is coupled to the first input of the first traveling-wave amplifier section, the first input of each of the plurality of additional traveling-wave amplifier sections is coupled to the delay of the previous traveling-wave amplifier, the first output of each of the plurality of additional traveling-wave amplifier sections except the last are coupled to the second input of the next additional traveling-wave amplifier section, the first output of the last additional traveling-wave amplifier section is coupled to the second input of the first traveling-wave amplifier section, and a second matched load is coupled to the second output of the last additional traveling-wave amplifier section.

23. The voltage controlled oscillator of claim 19 wherein the first traveling-wave amplifier section has a tunable frequency of oscillation.

24. The voltage controlled oscillator of claim 19 wherein the first traveling-wave amplifier section and the second traveling-wave amplifier section each have a tunable frequency of oscillation.

25. The voltage controlled oscillator of claim 19 wherein the first traveling-wave amplifier section and the second traveling-wave amplifier section each have a separately tunable frequency of oscillation.

26. The voltage controlled oscillator of claim 22 wherein each traveling-wave amplifier section has a tunable frequency of oscillation.

27. The voltage controlled oscillator of claim 22 wherein each traveling-wave amplifier section has a separately tunable frequency of oscillation.
